(19) United States
(12) Patent Application Publication
(10) Pub. No.: US 2023/0132423 A1
(43) Pub. Date: May 4, 2023

(54) LIGHT EMITTING DIODE ARRAY WITH INACTIVE IMPLANTED ISOLATION REGIONS AND METHODS OF FORMING THE SAME

(71) Applicant: NANOSYS, INC., Milpitas, CA (US)

(72) Inventors: Zhen CHEN, Dublin, CA (US); Saket CHADDA, San Jose, CA (US); Shuke YAN, San Jose, CA (US)

(21) Appl. No.: 18/049,667

(22) Filed: Oct. 26, 2022

Related U.S. Application Data
(60) Provisional application No. 63/274,704, filed on Nov. 2, 2021.

(51) Int. Cl. H01L 33/44; H01L 27/15; H01L 33/00; H01L 33/42; H01L 33/50; H01L 33/60; H01L 33/62

(52) U.S. Cl. CPC H01L 33/44; H01L 27/156; H01L 33/0093; H01L 33/42; H01L 33/50; H01L 33/60; H01L 33/62; H01L 2933/0016; H01L 2933/0025; H01L 2933/0041; H01L 2933/0066

(57) ABSTRACT

A method of forming a light emitting device includes forming a first doped compound semiconductor layer over a substrate, forming an active layer over the first doped compound semiconductor layer, forming a second doped compound semiconductor layer over the active layer, forming a patterned ion implantation mask layer, and implanting ions of at least one electrically inactive dopant species in portions of the active layer that are not masked by the patterned ion implantation mask layer. An electrically inactive insulating region including a semiconductor material and atoms of the at least one electrically inactive dopant species is formed. Unimplanted portions of the active layer constitute active regions of an array of light emitting diodes.

### FIELD

The present invention relates to light emitting diodes, and particularly to a light emitting diode array with inactive implanted isolation regions and methods of forming the same.

### BACKGROUND

Light emitting diodes (LEDs) are used in electronic displays, such as backlights in liquid crystal displays located in laptops or televisions, LED billboards, microdisplays, direct view displays, and LED televisions.

### SUMMARY

According to an aspect of the present disclosure, a light emitting device comprises an array of light emitting diodes, wherein each of the light emitting diodes comprises a vertical stack of a first doped compound semiconductor region, a second doped compound semiconductor region, and an active region configured to emit radiation at a peak wavelength located between the first and the second doped compound semiconductor regions, and an electrically inactive insulating region comprising a semiconductor material of the second doped compound semiconductor regions and atoms of at least one electrically inactive dopant species, laterally surrounding each of the active regions, and disposed between each neighboring pair of the active regions.

According to another aspect of the present disclosure, a method of forming a light emitting device includes forming a first doped compound semiconductor layer over a substrate, forming an active layer over the first doped compound semiconductor layer, forming a second doped compound semiconductor layer over the active layer, forming a patterned ion implantation mask layer, and implanting ions of at least one electrically inactive dopant species in portions of the active layer that are not masked by the patterned ion implantation mask layer. An electrically inactive insulating region including a semiconductor material and atoms of the at least one electrically inactive dopant species is formed. Unimplanted portions of the active layer constitute active regions of an array of light emitting diodes.

### BRIEF DESCRIPTION OF THE DRAWINGS

FIG. 1 is a vertical cross-sectional view of a region of a first exemplary structure after forming an active layer on a first doped compound semiconductor layer according to a first embodiment of the present disclosure.

FIG. 2 is a vertical cross-sectional view of a region of the first exemplary structure after formation of a patterned ion implantation mask layer according to the first embodiment of the present disclosure.

FIG. 3A is a vertical cross-sectional view of a region of the first exemplary structure after formation of an electrically inactive insulating region according to the first embodiment of the present disclosure.

FIG. 3B is a top-down view of the first exemplary structure of FIG. 3A.

FIG. 4 is a vertical cross-sectional view of a region of the first exemplary structure after formation of second doped compound semiconductor regions and an insulating spacer material layer according to the first embodiment of the present disclosure.

FIG. 5 is a vertical cross-sectional view of a region of the first exemplary structure after patterning the insulating spacer material layer into insulating spacers according to the first embodiment of the present disclosure.

FIG. 6 is a vertical cross-sectional view of a region of the first exemplary structure after formation of reflectors according to the first embodiment of the present disclosure.

FIG. 7 is a vertical cross-sectional view of a region of the first exemplary structure after attaching an array of light emitting diodes to a backplane according to the first embodiment of the present disclosure.

FIG. 8 is a vertical cross-sectional view of a region of the first exemplary structure after removing a single crystalline substrate from a compound semiconductor material substrate according to the first embodiment of the present disclosure.

FIG. 9 is a vertical cross-sectional view of a region of the first exemplary structure after formation of an array of color conversion medium portions according to the first embodiment of the present disclosure.

FIG. 10 is a vertical cross-sectional view of a region of a second exemplary structure after formation of an active layer according to a second embodiment of the present disclosure.

FIG. 11 is a vertical cross-sectional view of a region of the second exemplary structure after formation of second doped compound semiconductor regions and an insulating spacer material layer according to the second embodiment of the present disclosure.

FIG. 12 is a vertical cross-sectional view of a region of the second exemplary structure after patterning the insulating spacer material layer into insulating spacers according to the second embodiment of the present disclosure.

FIG. 13 is a vertical cross-sectional view of a region of the second exemplary structure after formation of reflectors according to the second embodiment of the present disclosure.

FIG. 14 is a vertical cross-sectional view of a region of the second exemplary structure after attaching an array of light emitting diodes to a backplane according to the second embodiment of the present disclosure.

FIG. 15 is a vertical cross-sectional view of a region of the second exemplary structure after removing a single crystalline substrate from a compound semiconductor material substrate according to the second embodiment of the present disclosure.

FIG. 16 is a vertical cross-sectional view of a region of the second exemplary structure after formation of a patterned ion implantation mask layer and an electrically inactive insulating region according to the second embodiment of the present disclosure.

FIG. 17 is a vertical cross-sectional view of a region of the second exemplary structure after formation of an array of color conversion medium portions according to the second embodiment of the present disclosure.

### DETAILED DESCRIPTION

A microLED refers to a light emitting diode having lateral dimensions that do not exceed 100 microns. A microLED has a typical lateral dimension in a range from 1 micron to 50 microns, such as 2 microns to 10 microns, for example 3 microns to 6 microns. Generally, external quantum efficiency of light emitting diodes decreases with a decrease in the size of the light emitting diodes. This is believed to be due to formation of dangling bonds at etched surfaces (i.e., sidewalls) of the light emitting diodes, which is a collateral consequence of etch processes employed to pattern light emitting diodes in order to electrically isolate neighboring pairs of light emitting diodes. The dangling bonds can consume mobile carriers (such as electrons and holes), which results in reduction of external quantum efficiency. As the size of the light emitting diodes decreases, the ratio of the sidewall surface area to the active quantum well area increases, and the external quantum efficiency decreases.

According to an embodiment of the present disclosure, regions between neighboring pairs of light emitting diodes are electrically inactivated by an ion implantation process that renders the implanted regions of a semiconductor material electrically insulating. Light emitting diodes are electrically isolated from each other by the electrically inactive implanted regions without forming etched surfaces or forming dangling bonds, and a light emitting diode array can be formed without significantly degrading external quantum efficiency of light emitting diodes.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The same reference numerals refer to the same element or similar element. Unless otherwise indicated, elements having the same reference numerals are presumed to have the same composition. As used herein, a first element located “on” a second element can be located on the exterior side of a surface of the second element or on the interior side of the second element. As used herein, a first element is located “directly on” a second element if there exist a physical contact between a surface of the first element and a surface of the second element. As used herein, a “layer” refers to a continuous portion of at least one material including a region having a thickness. A layer may consist of a single material portion having a homogeneous composition, or may include multiple material portions having different compositions.

As used herein, a “conductive material” refers to a material having electrical conductivity greater than 1.0×10⁵ S/cm. As used herein, an “insulator material” or a “dielectric material” refers to a material having electrical conductivity less than 1.0×10⁻⁶ S/cm. As used herein, a “semiconducting material” refers to a material having electrical conductivity in the range from 1.0×10⁻⁶ S/cm to 1.0×10⁵ S/cm. As used herein, a “metallic material” refers to a conductive material including at least one metallic element therein. All measurements for electrical conductivities are made at the standard condition.

A display device, such as a direct view display can be formed from an ordered array of pixels. Each pixel can include a set of subpixels that emit light at a respective emission spectrum. For example, a pixel can include a red subpixel, a green subpixel, and a blue subpixel. Each subpixel can include one or more light emitting diodes that emit light of a particular peak wavelength.

Alternatively, all light emitting diodes in each subpixel emit light of the same peak wavelength, such as blue light or ultraviolet (UV) radiation. A different color conversion medium, such as color converting quantum dots, phosphor or dye is located over each light emitting diode. For example, a red color conversion medium can be located over the blue or UV light emitting diode in the red subpixel, a green color conversion medium can be located over the blue or UV light emitting diode in the green subpixel, and a blue color conversion medium can be located over the blue or UV light emitting diode in the blue subpixel. Alternatively, the blue color conversion medium may be omitted if a blue light emitting diode is used in the blue subpixel.

Each pixel is driven by a backplane circuit (e.g., thin film transistor (TFT) array on an insulating substrate or a CMOS array on a silicon substrate) such that any combination of colors within a color gamut may be shown on the display for each pixel. The display panel can be formed by a process in which LED subpixels are soldered to, or otherwise electrically attached to, a bond pad located on a backplane. The bond pad is electrically driven by the backplane circuit and other driving electronics.

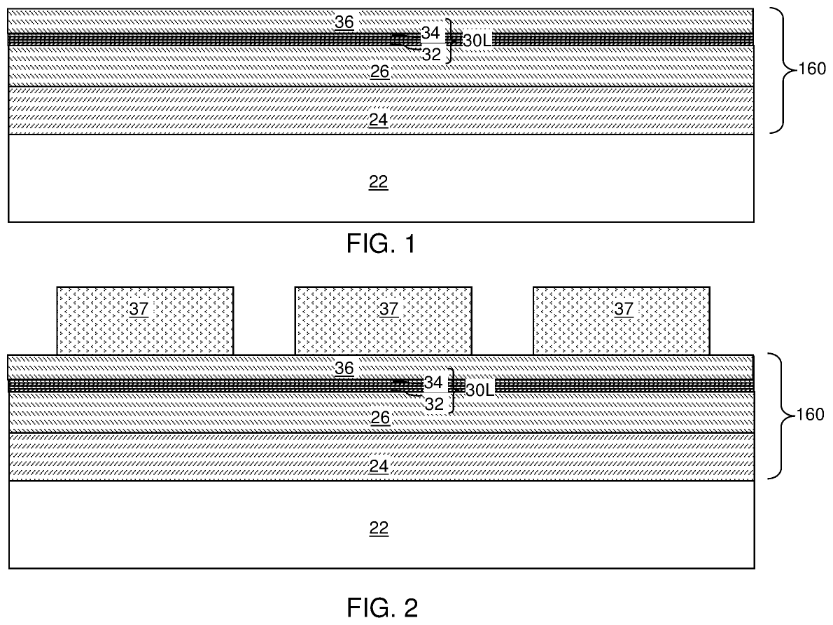

Referring to FIG. 1, a first exemplary structure according to a first embodiment of the present disclosure comprises a substrate 22. The substrate 22 may comprise a single crystalline material on which a semiconductor material can be epitaxially grown. For example, the single crystalline substrate 22 may comprise a commercially available patterned sapphire substrate (PSS) on which a III-V compound semiconductor material, such as gallium nitride can be epitaxially grown.

A buffer layer 24 and a first doped compound semiconductor layer 26 (such as an n-doped GaN layer) having a doping of a first conductivity type can be epitaxially grown from the top surface of the single crystalline substrate 22. In an illustrative example, the buffer layer 24 may comprise a buffer III-V compound semiconductor material having a doping of the first conductivity type, and may have a lattice constant that is substantially matched to the lattice constant of the single crystalline substrate 22. In some embodiment, the buffer layer 24 may have a compositional gradient so that the top portion of the buffer layer 24 has a lattice constant of a first doped compound semiconductor material of the first doped compound semiconductor layer 26. In an illustrative example, the first conductivity type may be n-type. The thickness of the buffer layer 24 may be in a range from 0.5 micron to 10 microns, such as from 1 micron to 3 microns, although lesser and greater thicknesses may also be employed.

In a non-limiting illustrative example, the first doped compound semiconductor layer 26 may comprise a single crystalline gallium nitride material in epitaxial alignment with the single crystalline structure of the single crystalline substrate 22. The single crystalline n-doped gallium nitride layer 26 may be formed, for example, by an epitaxial deposition process such as metal-organic chemical vapor deposition (MOCVD) process. The single crystalline n-doped gallium nitride layer may be n-doped by introduction of silicon as n-type dopants during the epitaxial deposition process.

An active layer 30L can be formed over the first doped compound semiconductor layer 26 by performing a series of epitaxial deposition processes. The active layer 30L includes a set of doped compound semiconductor material layers that is configured to emit radiation at a peak wavelength. In one embodiment, the active layer 30L may comprise a periodic repetition of first compound semiconductor layers 32 and second compound semiconductor layers 34 that form one or more quantum wells. Additional material layers configured to increase the quantum efficiency of the light emission may be present within the active layer 30L. Alternatively, non-quantum-well structures may be employed for the active layer 30L. In a non-limiting illustrative example, the active layer 30L may comprise a planar light-emitting indium gallium nitride quantum well layer 32 located between a planar GaN or AlGaN barrier layer. Generally, the active layer 30L may comprise any set of doped compound semiconductor material layers that is configured to emit light at a peak wavelength.

A second doped compound semiconductor layer 36 is formed on the active layer 30L. The second doped compound semiconductor layer 36 includes a doped semiconductor material having a doping of a second conductivity type that is the opposite of the first conductivity type. In an illustrative example, the first doped compound semiconductor layer 26 may comprise an n-doped III-V compound semiconductor material (such as n-doped GaN), and the second doped compound semiconductor layer 36 may comprise a p-doped III-V compound semiconductor material (such as p-doped GaN or AlGaN). In one embodiment, the second doped compound semiconductor layer 36 may be formed by epitaxial growth of a doped compound semiconductor material having a doping of the second conductivity type. The second doped compound semiconductor layer 36 may have a thickness in a range from 100 nm to 1 micron, such as from 200 nm to 500 nm, although lesser and greater thicknesses may also be employed.

The combination of all semiconductor material layers located above the single crystalline substrate 22 constitutes a stack 160. The stack 160 includes the buffer layer 24, the first doped compound semiconductor layer 26, the active layer 30L, and second doped compound semiconductor region 36.

Referring to FIG. 2, a mask material (such as a photoresist material) can be applied over the stack 160, and can be lithographically patterned to form a patterned ion implantation mask layer 37. In one embodiment, the patterned ion implantation mask layer 37 may comprise a patterned photoresist layer. In one embodiment, the patterned ion implantation mask layer 37 may comprise a two-dimensional array of discrete mask material portions. In one embodiment, the two-dimensional array of discrete mask material portions may be arranged as a rectangular array or as a hexagonal array. Thus, an unmasked portion of the stack 160 may be present between each neighboring pair of patterned mask material portions. In one embodiment, the two-dimensional array of discrete mask material portions may have a first pitch along a first horizontal direction, and a second pitch along a second horizontal direction. The first pitch and the second pitch may be in a range from 1 micron to 100 microns, such as from 2 microns to 10 microns, although lesser and greater pitches may also be employed.

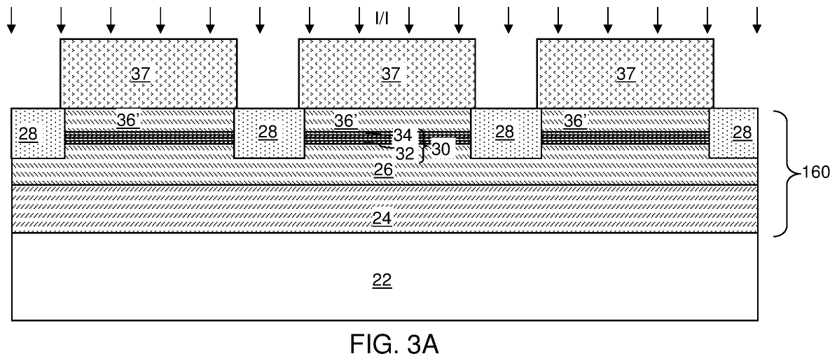

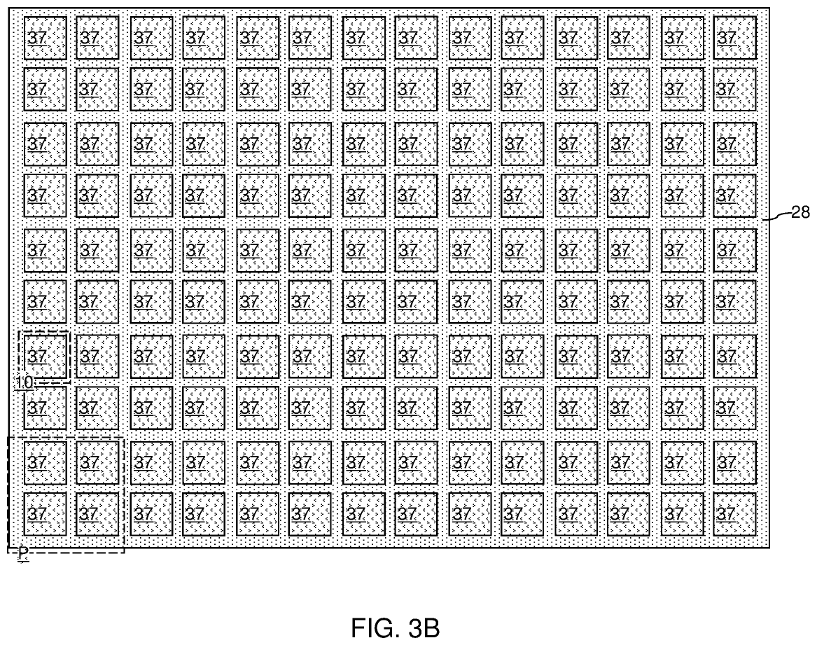

Referring to FIGS. 3A and 3B, ions of at least one electrically inactive dopant species can be implanted in portions of the active layer 30L that are not masked by the patterned ion implantation mask layer 37. In one embodiment, each of the at least one electrically inactive dopant species may be selected from oxygen or nitrogen. An electrically inactive insulating region 28 comprising the compound semiconductor material and atoms of the at least one electrically inactive dopant species is formed within implanted portions of the stack 160. Unimplanted portions of the active layer 30L comprise active regions 30. Each of the active regions 30 includes a respective portion of the active layer 30L. In one embodiment, each active region 30 may comprise a periodic repetition of first compound semiconductor layers 32 and second compound semiconductor layers 34. Unimplanted portions of the second doped compound semiconductor layer 36 comprise second doped compound semiconductor regions 36′.

In one embodiment, the electrically inactive insulating region 28 comprises the at least one electrically inactive dopant species at an atomic percentage in a range from 1×10²¹ cm⁻³ to 10%, such as from 0.01% to 5%, and/or from 0.1% to 1%. The electrically inactive insulating region 28 may be damaged by the ion implantation and may be rendered at least partially amorphous depending on the energy and the dose of the at least one electrically inactive dopant species. Typically, damaged (0001) plane III-nitride (e.g., GaN, InGaN and/or AlGaN) crystallinity is not restored by annealing. Furthermore, the ions may be implanted very deep through the (0001) top surface of the hexagonal lattice structure of GaN, resulting in deep insulating regions 28 which extend below the bottom of the active regions 30.

In one embodiment, the electrically inactive insulating region 28 comprises, and/or consists essentially of, a compound of a semiconductor material (e.g., a III-nitride material) and atoms of at least one electrically inactive dopant species, such as oxygen or additional nitrogen. If nitrogen is used as the inactive dopant species, then the III-nitride material comprises a nitrogen rich III-nitride material having a Group III to nitrogen atom ratio of less than 1.

The electrically inactive insulating region 28 laterally surrounds each of the active regions 30 and each of the second doped compound semiconductor regions 36′, and disposed between each neighboring pair of the active regions 30 and each neighboring pair of the second doped compound semiconductor regions 36′. In one embodiment, each active region 30 and each of the second doped compound semiconductor regions 36′ may be located within a respective opening in the electrically inactive insulating region 28.

In one embodiment, horizontal top surfaces of the second doped compound semiconductor regions 36′ can be located within a same horizontal plane as a first horizontal surface of the electrically inactive insulating region 28. In one embodiment, the bottommost portions of the electrically inactive insulating region 28 may be formed between the horizontal plane including the top surface of the first doped compound semiconductor layer 26 and the horizontal plane including the bottom surface of the first doped compound semiconductor layer 26. In one embodiment, the electrically inactive insulating region 28 comprises sidewalls and a horizontal surface that contact surfaces of the first doped compound semiconductor layer 26.

As shown in FIG. 3B, four regions of the mask layer 37 disposed in a rectangular array and surrounded by the electrically inactive insulating region 28 correspond to an area of a pixel “P” of a display device. A two-dimensional array of second doped compound semiconductor regions 36′ is located over the two-dimensional array of active regions 30. Each second doped compound semiconductor region 36′ is located on a top surface of a respective active region 30 under a respective region of the mask layer 37. The patterned ion implantation mask layer 37 can be subsequently removed. For example, if the patterned ion implantation mask layer 37 comprises a patterned photoresist layer, the patterned ion implantation mask layer 37 may be removed by ashing.

Referring to FIG. 3B, an array of light emitting diodes 10 is formed over the single crystalline substrate 22. Each light emitting diode 10 includes a first doped compound semiconductor region that is a portion of the first doped compound semiconductor layer 26, an active region 30 that is configured to emit radiation (e.g., visible light or UV radiation) under electrical bias, and a second doped compound semiconductor region 36′. There may be four light emitting diodes 10 in each pixel “P”, where the region of each light emitting diode 10 corresponds to a subpixel of the pixel. In one embodiment, interfaces between the second doped compound semiconductor regions 36 and the active regions 30 are located within a horizontal plane including a horizontal surface of the electrically inactive insulating region 28.

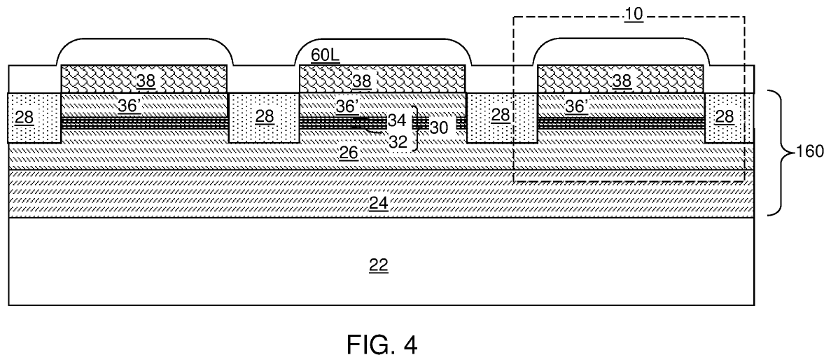

Referring to FIG. 4, an optional p-side electrode 38 may be formed on each second doped compound semiconductor region 36 in each light emitting diode 10. The p-side electrode 38 may comprise an optically transparent, electrically conductive material, such as a transparent conductive oxide. Examples of a transparent conductive oxide include indium tin oxide, aluminum zinc oxide, or fluorine doped tin oxide. The optically transparent, electrically conductive material may be deposited as a blanket layer over the stack 160 followed by photolithography and etching to form the p-side electrodes 38 in each light emitting diode 10. Alternatively, the p-side electrode may be formed in a later step.

An insulating spacer material layer 60L may be formed over the two-dimensional array of second doped compound semiconductor regions 36 and the p-side electrodes 38. The insulating spacer material layer 60L includes an insulating material such as silicon oxide, silicon nitride, and/or a dielectric metal oxide (such as aluminum oxide), and may have a thickness in a range from 100 nm to 2 microns, such as from 200 nm to 1 micron, although lesser and greater thicknesses may also be employed.

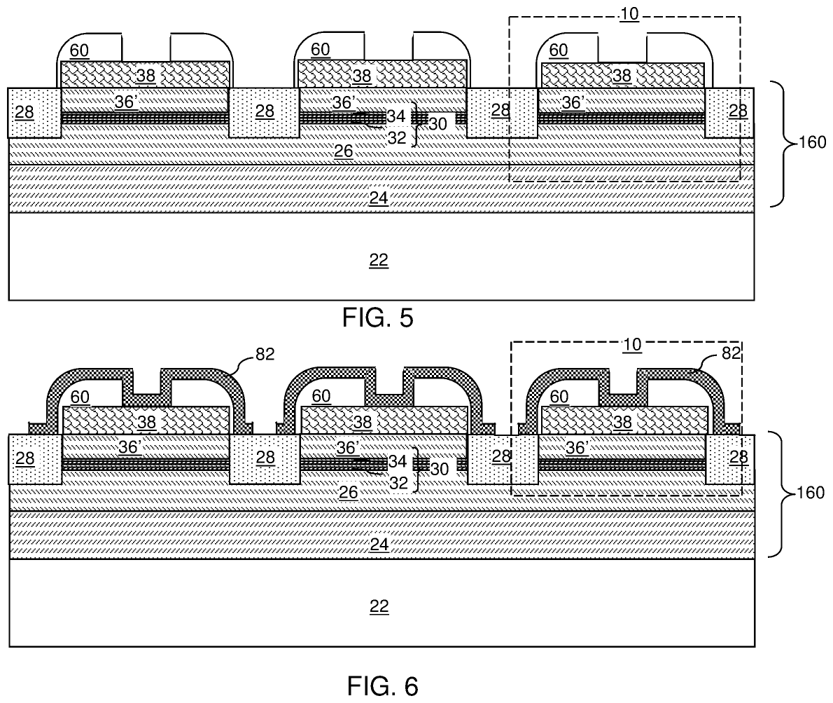

Referring to FIG. 5, the insulating spacer material layer 60L can be patterned into a two-dimensional array of insulating spacers 60, for example, by applying and patterning a photoresist layer over the insulating spacer material layer 60L, and by transferring the pattern in the patterned photoresist layer into the insulating spacer material layer 60L (e.g., by etching unmasked portions of layer 60L). The patterned portions of the insulating spacer material layer 60L comprise the two-dimensional array of insulating spacers 60. In one embodiment, each insulating spacer 60 can be formed on a respective one of the second doped compound semiconductor region 36 and the p-side electrode 38 of each light emitting diode 10. In one embodiment, each insulating spacer 60 may comprise at least one opening in which a surface of an underlying p-side electrode 38 is physically exposed. Each insulating spacer 60 can be incorporated into a respective light emitting diode 10. Thus, the array of light emitting diodes 10 comprises an array of insulating spacers 60 located over options p-side electrodes 38.

Referring to FIG. 6, a reflective material that reflects radiation within a wavelength range of the radiation emitted from the active regions 30 can be deposited over the insulating spacers 60, the p-side electrodes 38, and second doped compound semiconductor regions 36, and the electrically inactive insulating region 28. In one embodiment, reflective material may comprise a metallic material such as aluminum, silver, and/or gold. The metallic material is spaced from the active regions 30 by the insulating spacers 60 to prevent an electrical short between the reflective material and the active regions 30. The reflective material can be patterned, for example, by applying and patterning photoresist layer (not shown) over the insulating spacers 60 and by transferring the pattern in the patterned photoresist layer through the reflective material (i.e., by etching the reflective material). Each patterned portion of the reflective material constitutes a reflector 82. In one embodiment, each reflector 82 is electrically connected to a respective second doped compound semiconductor region 36 either by directly contacting the respective second doped compound semiconductor region 36, or by contacting the p-side electrode 38 that is in contact with the respective second doped compound semiconductor region 36. Each reflector 82 is incorporated into a respective light emitting diode 10.

Generally, an array of reflectors 82 can be formed over the second doped compound semiconductor regions 36. The array of reflectors 82 is electrically isolated from the active regions 30, and may contact surface segments of the electrically inactive insulating region 28. The array of light emitting diodes 10 comprises an array of reflectors 82 configured to reflect radiation emitted from the active regions 30 such that the radiation exits downward toward the buffer layer 24. In one embodiment, each insulating spacer 60 of the array of insulating spacers 60 comprises an opening through which a portion of a respective reflector 82 of the array of reflectors 82 extends vertically to contact, and/or to provide electrical connection to, a respective one of the second doped compound semiconductor regions 36. An array of insulating spacers 60 is disposed between the array of active regions 30 and the array of reflectors 82.

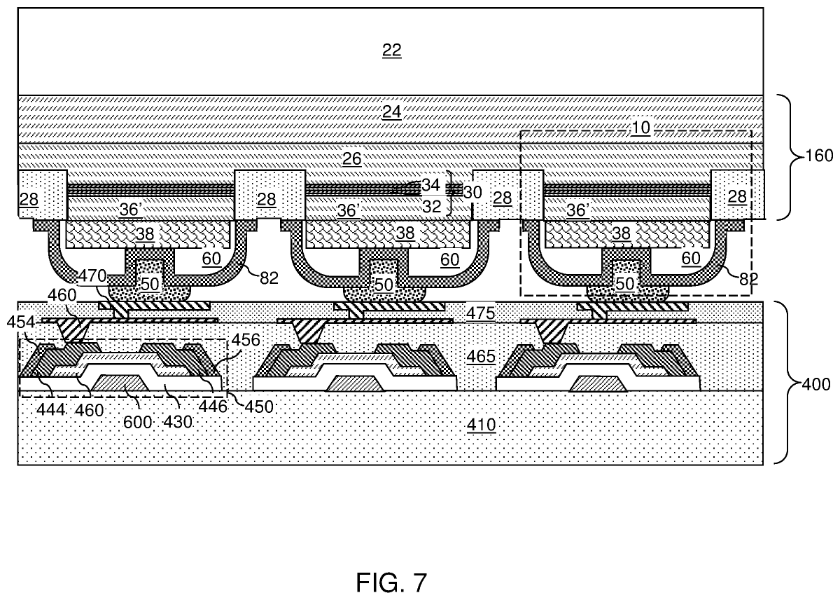

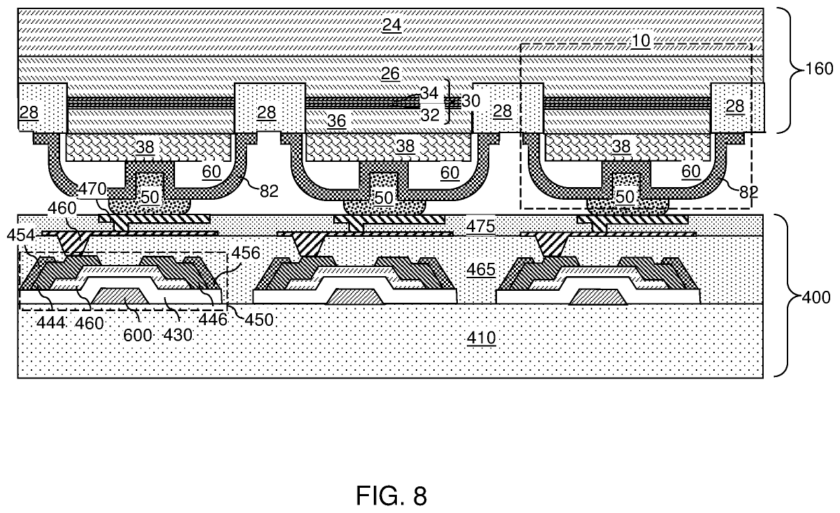

Referring to FIG. 7, a backplane 400 is provided. The backplane 400 includes a backplane substrate 410, which can be an insulating substrate (e.g., glass or plastic substrate) or a semiconductor substrate (e.g., silicon wafer). A control circuitry for controlling operation of the light emitting diodes 10 attached to the backplane 400 may be provided on and/or in the backplane. For example, switching devices 450 can be provided within the backplane 400. In an illustrative example, the switching devices 450 can include field effect transistors, such as thin film transistors (TFTs). In this case, each field effect transistor 450 may include a gate electrode 420, a gate dielectric 430, a channel region 442, a source region 446, and a drain region 444. While an inverted staggered TFT 450 is shown in FIG. 7, other types of TFTs, such as inverted coplanar, top gated staggered and top gated coplanar TFTs can be used instead. Alternatively, bulk transistors, such as transistors in a CMOS configuration can be used instead of the TFTs. Various electrical wirings can be provided to interconnect the various electrical nodes of the field effect transistors to electrical interfaces (not expressly shown) on the backplane 400. A patterned passivation layer 454 may be optionally formed on the source regions 446 and the drain regions 444. Additional interconnect wiring may be provided as needed. The switching devices 450 can be encapsulated by an encapsulation dielectric layer 465. First-level metal interconnect structures 460 can be formed through the encapsulation dielectric layer 465 to a node of a respective switching device 450 such as a drain region 444. An interconnect level dielectric layer 475 may be formed over the encapsulation dielectric layer 465, and second-level metal interconnect structures 470 can be formed through the interconnect level dielectric layer 475 on the first-level metal interconnect structures 460. The second-level metal interconnect structures 470 can include an array of bonding pads for attaching the array of light emitting diodes 10.

The first exemplary structure illustrated in FIG. 6 can be attached to the backplane 400, for example, through an array of solder contacts, such as an array of solder material portions 50. For example, the array of solder material portions 50 can be formed on the reflectors 82, and can be bonded to a respective metal bonding structure in the backplane 400, which may be a metal interconnect structure such as a second-level metal interconnect structure 470. Alternatively or additionally, the array of solder material portions 50 may be formed on metal bonding structures in the backplane 400 (such as the second-level metal interconnect structures 470), and can be bonded to a respective one of the recess regions of the reflectors 82. Generally, a structure including the array of light emitting diodes 10, the stack 160, and the single crystalline substrate 22 may be attached to the backplane 400. While the present disclosure is described employing a backplane 400 including two levels of metal interconnect structures (460, 470), it is understood that the backplane 400 may include any number of metal interconnect levels. Generally, an array of bonding structures can be provided on the front side of the backplane 400, and the array of light emitting diodes 10 can be bonded to a respective bonding structure within the backplane 400 employing any bonding method known in the art, such as thermal or laser bonding. The laser bonding may include irradiating the solder material portions 50 with an infrared laser through the light emitting diodes 10.

Referring to FIG. 8, the single crystalline substrate 22 can be detached from the stack 160, for example, by laser lift off, cleaving, grinding, polishing, and/or etching. The backside horizontal surface of the buffer layer 24 (or the backside horizontal surface of the first doped compound semiconductor layer 26 in case a buffer layer 24 is not employed) can be physically exposed upon removal of the single crystalline substrate 26. The single crystalline substrate 22 can be detached from the array of light emitting diodes 10 before or after attaching the array of light emitting diodes 10 to the backplane 400.

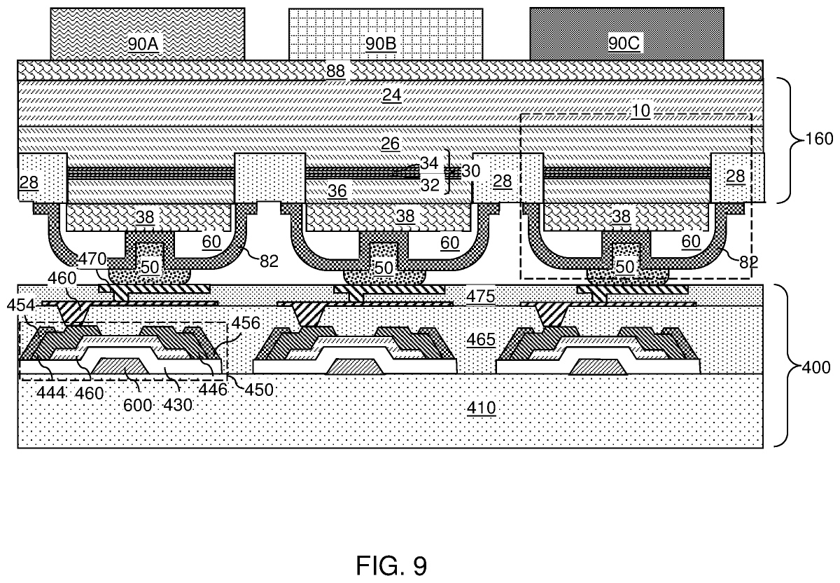

Referring to FIG. 9, a common n-side electrode 88 is formed on or in electrical contact with the first doped compound semiconductor layer 26. The n-side electrode 88 may comprise an optically transparent, electrically conductive material, such as a transparent conductive oxide. Examples of a transparent conductive oxide include indium tin oxide, aluminum zinc oxide, or fluorine doped tin oxide. The n-side electrode 88 may be connected to the backplane 400 circuitry outside the area of the array of the light emitting diodes 10.

Arrays of color conversion medium portions (90A, 90B, 90C) can be formed over the n-side electrode 88 and the stack 160 that includes the first doped compound semiconductor layer 26. Each color conversion medium portion (90A, 90B, 90C) comprises a material that converts incident radiation into an emission light having a different wavelength than the incident radiation. For example, the incident radiation emitted by the active regions 30 of the light emitting diodes 10 may be a blue light (which includes radiation in the blue and violet range of the color spectrum) or an ultraviolet radiation, and the emission light that is emitted from the color conversion medium portions (90A, 90B, 90C) may be light having a longer wavelength than the incident radiation. For example, the color conversion medium portions (90A, 90B, 90C) may comprise quantum dots, phosphor or dye that emits light upon excitation by the incident radiation. In an illustrative example, the emission lights from the color conversion medium portions (90A, 90B, 90C) may comprise a red light, a green light, and a blue light. Each of the color conversion medium portions (90A, 90B, 90C) may be located in a respective subpixel (e.g., red, green or blue light emitting subpixel) of a pixel of a display device. In one embodiment, if the light emitting diodes 10 emit blue light, then the color conversion medium portion (e.g., 90C) may be omitted over the blue light emitting subpixels.

Generally, the arrays of color conversion medium portions (90A, 90B, 90C) can be formed over the first doped compound semiconductor layer 26 after detaching the single crystalline substrate 22 from the array of light emitting diodes 10. In one embodiment, the arrays of color conversion medium portions (90A, 90B, 90C) may comprise first color conversion medium portions 90A overlying a first subset of the light emitting diodes 10 and configured to convert incident radiation into a first emission light having a first peak wavelength (such as red light), second color conversion medium portions 90B overlying a second subset of the light emitting diodes 10 and configured to convert incident radiation into a second emission light having a second peak wavelength (such as green light), and optionally third color conversion medium portions 90C overlying a third subset of the light emitting diodes 10 and configured to convert incident light into a third emission radiation having a third peak wavelength (such as blue light). In one embodiment, the first peak wavelength, the second peak wavelength, and the third peak wavelength are different from each other.

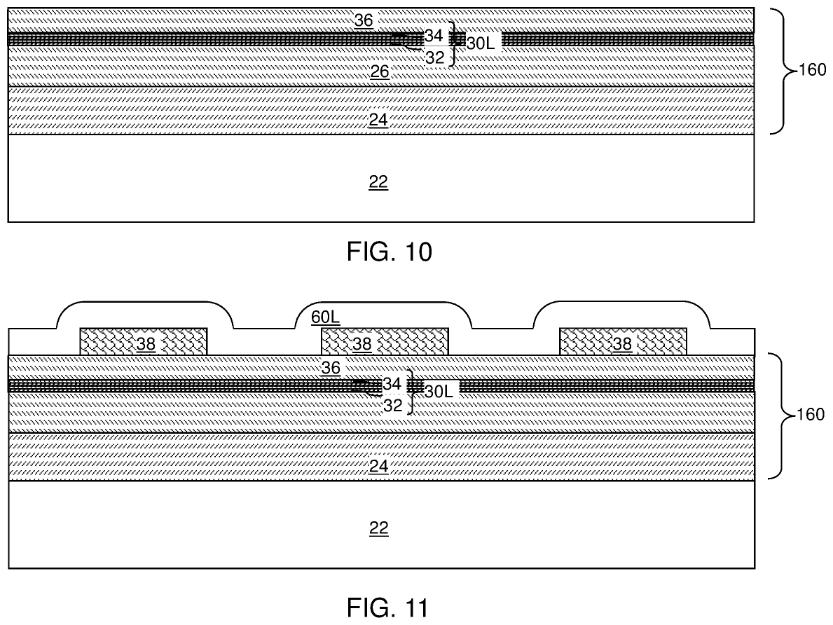

Referring to FIG. 10, a second exemplary structure according to a second embodiment is illustrated after formation of the second doped compound semiconductor layer 36. The second exemplary structure of FIG. 10 may be the same as the first exemplary structure of FIG. 1.

Referring to FIG. 11, the processing steps of FIGS. 2, 3A, and 3B can be omitted, and the processing steps of FIG. 4 can be performed to form the array of p-side electrodes 38 and the insulating spacer material layer 60L.

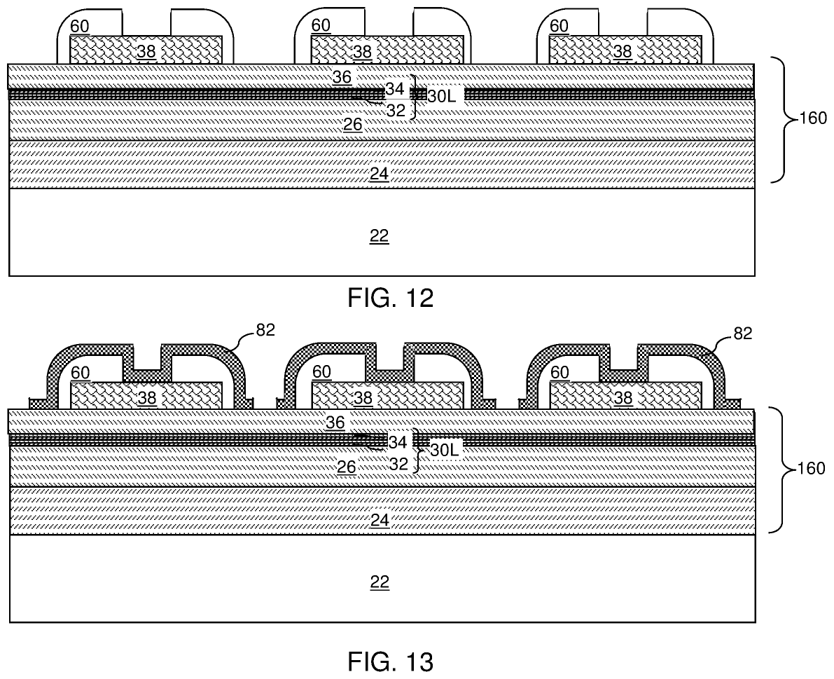

Referring to FIG. 12, the processing steps of FIG. 5 can be performed to pattern the insulating spacer material layer 60L into an array of insulating spacers 60.

Referring to FIG. 13, the processing steps of FIG. 6 can be performed to form an array of reflectors 82 over the array of insulating spacers 60. The reflectors 82 may contact surface segments of the top surface of the second doped compound semiconductor layer 36. Each reflector 82 may contact, and/or may be electrically shorted to, a respective second doped compound semiconductor layer 36 and the p-side electrode 38.

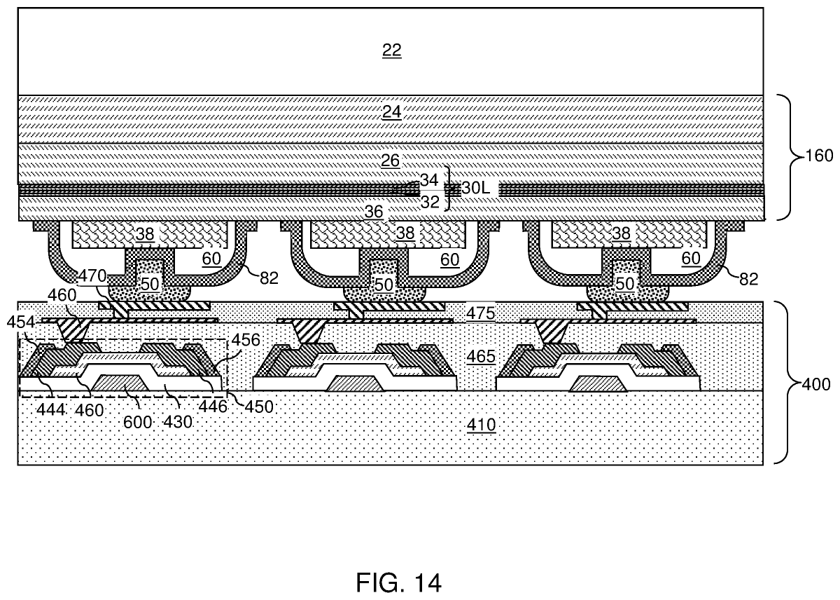

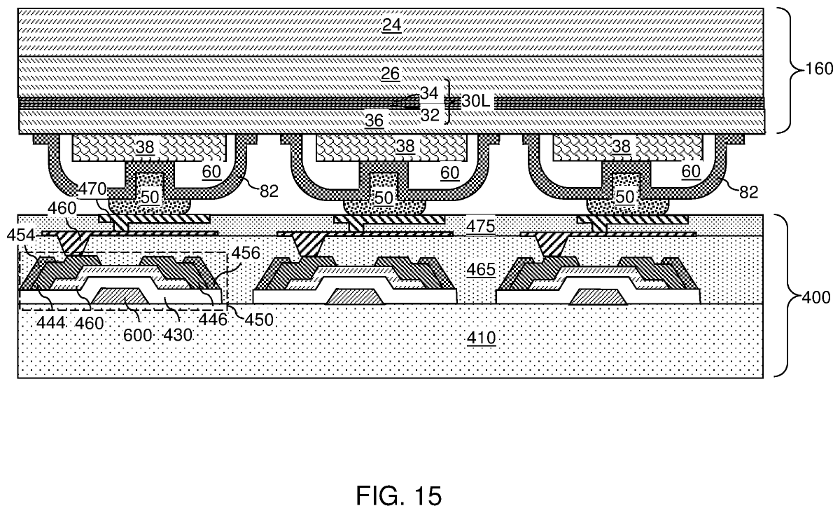

Referring to FIG. 14, the processing steps of FIG. 7 can be performed to attach the second exemplary structure illustrated in FIG. 13 to a backplane 400. Each light emitting diode 10 can be electrically connected to a respective switching device 450 in the backplane 400.

Referring to FIG. 15, the processing steps of FIG. 8 can be performed to remove the single crystalline substrate 22 from the array of light emitting diodes 10. Optionally, the buffer layer 24 may be thinned or removed, for example, by chemical mechanical polishing. In case the buffer layer 24 is removed, the first doped compound semiconductor layer 26 may be optionally thinned. Generally, the total thickness of the stack 160 may be controlled such that ions of at least one electrically inactive dopant species to be subsequently implanted into the stack 160 can be implanted into the active layer 30L and the second compound semiconductor layer 36 from the backside (the distal side) of the stack 160.

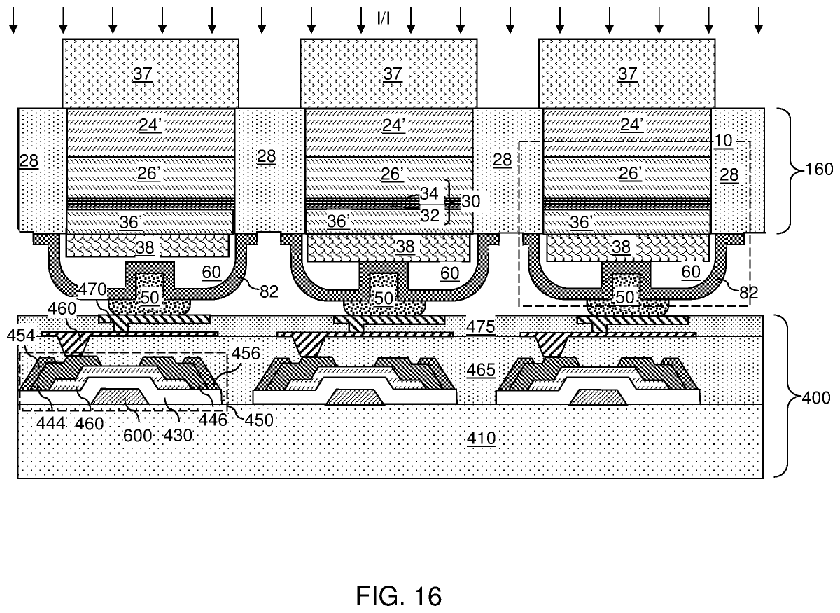

Referring to FIG. 16, a mask material (such as a photoresist material) can be applied over the backside surface (i.e., the distal horizontal surface) of the stack 160, and can be lithographically patterned to form a patterned ion implantation mask layer 37. In one embodiment, the patterned ion implantation mask layer 37 may comprise a patterned photoresist layer. In one embodiment, the patterned ion implantation mask layer 37 may comprise a two-dimensional array of discrete mask material portions (which are shown in FIG. 3B). Each discrete mask material portion of the patterned ion implantation mask layer 37 overlies, and has an areal overlap with, a respective light emitting diode 10. In one embodiment, the two-dimensional array of discrete mask material portions may be arranged as a rectangular array or as a hexagonal array. In one embodiment, the two-dimensional array of discrete mask material portions may have a first pitch along a first horizontal direction, and a second pitch along a second horizontal direction. The first pitch and the second pitch may be the same as in the prior embodiment.

Ions of at least one electrically inactive dopant species can be implanted into portions of the stack 160 that are not masked by the patterned ion implantation mask layer 37. In one embodiment, each of the at least one electrically inactive dopant species may be selected from oxygen or nitrogen. The above described electrically inactive insulating region 28 is formed within implanted portions of the stack 160.

Unimplanted portions of the second doped compound semiconductor layer 36 comprise first doped compound semiconductor regions 36′. Each second doped compound semiconductor region 36′ comprises a respective unimplanted portion of the first doped compound semiconductor layer 36. Unimplanted portions of the active layer 30L comprise active regions 30. Each of the active regions 30 includes a respective portion of the active layer 30L.

In one embodiment, each active region 30 may comprise a periodic repetition of first compound semiconductor layers 32 and second compound semiconductor layers 34. Unimplanted portions of the first doped compound semiconductor layer 26 comprise first doped compound semiconductor regions 26′. Each first doped compound semiconductor region 26′ comprises a respective unimplanted portion of the first doped compound semiconductor layer 26. Unimplanted portions of the buffer layer 24, if present, comprise buffer portions 24′. The buffer portions 24′, if present, comprise a respective unimplanted portion of the buffer layer 24.

The electrically inactive insulating region 28 may vertically extend from a proximal horizontal surface of the stack 160 (which is the front surface of the second doped compound semiconductor layer 36) to a distal horizontal surface of the stack 160 (which may be a backside surface of the buffer layer 24 or the backside surface of the first doped compound semiconductor layer 26). The patterned ion implantation mask layer 37 can be subsequently removed. For example, if the patterned ion implantation mask layer 37 comprises a patterned photoresist layer, the patterned ion implantation mask layer 37 may be removed by ashing.

The electrically inactive insulating region 28 vertically extends from a first horizontal surface (i.e., the proximal horizontal surface) of the stack 160 that is proximal to the backplane 400 to a second horizontal surface (i.e., the distal horizontal surface) of the stack 160 that is distal from the backplane 400.

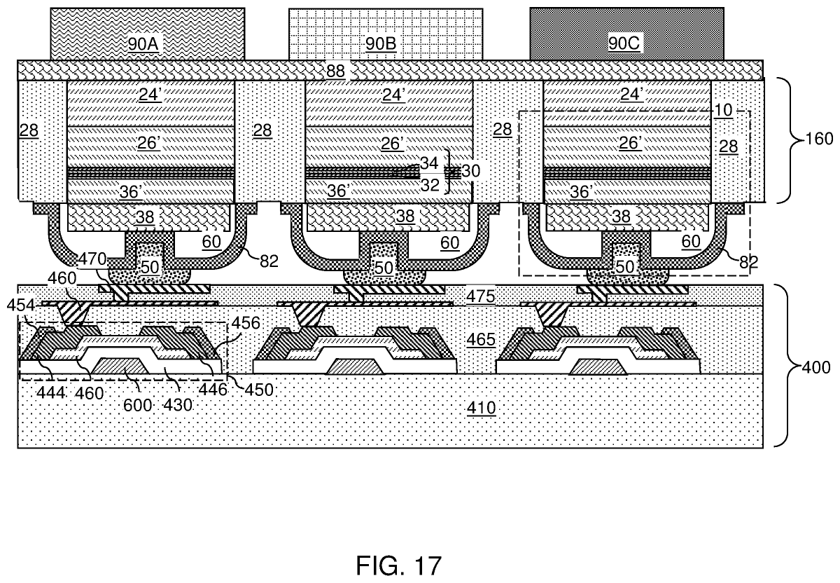

Referring to FIG. 17, common n-side electrode 88 and arrays of color conversion medium portions (90A, 90B, 90C) can be formed over the stack 160, as described above with respect to FIG. 9.

Thus, in the first embodiment of FIGS. 1-8, the electrically inactive insulating region 28 is formed prior to bonding the light emitting diodes 10 to the backplane 400. In contrast, in the second embodiment of FIGS. 10-17, the electrically inactive insulating region 28 is formed after to bonding the light emitting diodes 10 to the backplane 400. In both embodiments, the entire array of light emitting diodes 10 can be transferred to the backplane 400 during the same transfer step, without requiring the more complex, separate, sequential transfer of etch separated light emitting diodes 10 to the backplane 400.

In one embodiment, each of the light emitting diodes 10 comprises a micro light emitting diode having lateral dimensions which are less than 100 microns; and the active regions of the array of light emitting diodes 10 have a same composition and are configured to emit radiation at a same peak wavelength. The electrically inactive insulating region 28 is at least partially amorphous while the active region 30 and the first and the second doped compound semiconductor regions (26′, 36′) are single crystalline.

The preceding description of the disclosed embodiments is provided to enable any person skilled in the art to make or use the present invention. Various modifications to these embodiments will be readily apparent to those skilled in the art, and the generic principles defined herein may be applied to other embodiments without departing from the spirit or scope of the invention. Thus, the present invention is not intended to be limited to the embodiments shown herein but is to be accorded the widest scope consistent with the following claims and the principles and novel features disclosed herein.

1. A light emitting device, comprising:
an array of light emitting diodes, wherein each of the light emitting diodes comprises a vertical stack of a first doped compound semiconductor region, a second doped compound semiconductor region, and an active region configured to emit radiation at a peak wavelength located between the first and the second doped compound semiconductor regions; and
an electrically inactive insulating region comprising a semiconductor material of the second doped compound semiconductor regions and atoms of at least one electrically inactive dopant species, laterally surrounding each of the active regions, and disposed between each neighboring pair of the active regions.

2. The light emitting device of claim 1, wherein:
the electrically inactive insulating region is at least partially amorphous; and
the active region and the first and the second doped compound semiconductor regions are single crystalline.

3. The light emitting device of claim 2, wherein:
the first doped compound semiconductor regions are portions of a continuous first doped compound semiconductor layer; and
the electrically inactive insulating region comprises sidewalls and a horizontal surface that contact surfaces of the first doped compound semiconductor layer.

4. The light emitting device of claim 2, wherein:
the first doped compound semiconductor regions of adjacent light emitting diodes are separated from each other by the electrically inactive insulating region; and
the electrically inactive insulating region comprises sidewalls that contact entire sidewalls of each of the first doped compound semiconductor regions.

5. The light emitting device of claim 1, wherein the at least one electrically inactive dopant species comprises oxygen or nitrogen.

6. The light emitting device of claim 1, wherein:
each of the light emitting diodes comprises a micro light emitting diode having lateral dimensions which are less than 100 microns; and
the active regions of the array of light emitting diodes have a same composition and are configured to emit radiation at a same peak wavelength.

7. The light emitting device of claim 1, further comprising a backplane, wherein the array of light emitting diodes attached to a front side of the backplane.

8. The light emitting device of claim 7, further comprising a common transparent conductive n-side electrode located over the first doped compound semiconductor regions of the array of light emitting diodes.

9. The light emitting device of claim 8, wherein each of the light emitting diodes further comprises a discrete transparent conductive p-side electrode contacting the second doped compound semiconductor region.

10. The light emitting device of claim 9, wherein the array of light emitting diodes further comprises an array of reflectors interposed between the backplane and the second doped compound semiconductor regions and configured to reflect radiation emitted from the active regions away from the backplane, wherein the array of reflectors is bonded to the front side of the backplane.

11. The light emitting device of claim 10, wherein:
the array of light emitting diodes further comprises an array of insulating spacers disposed between the active regions and the array of reflectors; and
each of the insulating spacers comprises an opening through which a portion of a respective reflector of the array of reflectors extends vertically to contact a respective one of the p-side electrodes.

12. The light emitting device of claim 1, further comprising:
first color conversion medium portions overlying a first subset of the light emitting diodes of the array of the light emitting diodes and configured to convert incident radiation emitted by first subset of the light emitting diodes into a first emission light having a first peak wavelength longer than the indicated radiation wavelength; and
second color conversion medium portions overlying a second subset of the light emitting diodes of the array of the light emitting diodes and configured to convert incident radiation emitted by the second subset of the light emitting diodes into a second emission light having a second peak wavelength longer than the first peak wavelength.

13. A method of forming a light emitting device, comprising:
forming a first doped compound semiconductor layer over a substrate;
forming an active layer over the first doped compound semiconductor layer;
forming a second doped compound semiconductor layer over the active layer;
forming a patterned ion implantation mask layer; and
implanting ions of at least one electrically inactive dopant species in portions of the active layer that are not masked by the patterned ion implantation mask layer, wherein an electrically inactive insulating region comprising a semiconductor material and atoms of the at least one electrically inactive dopant species is formed, and wherein unimplanted portions of the active layer comprise active regions of an array of light emitting diodes.

14. The method of claim 13, wherein:
the electrically inactive insulating region is at least partially amorphous; and
the active layer and the first and the second doped compound semiconductor layers are single crystalline.

15. The method of claim 13, further comprising:
attaching the array of light emitting diodes to a backplane; and
detaching the substrate from the array of light emitting diodes after attaching the array of light emitting diodes to the backplane.

16. The method of claim 15, further comprising forming a common transparent conductive n-side electrode over the first doped compound semiconductor regions of the array of light emitting diodes after detaching the substrate.

17. The method of claim 16, further comprising forming arrays of color conversion medium portions over the common transparent conductive n-side electrode.

18. The method of claim 16, wherein:
the patterned ion implantation mask layer is formed over second doped compound semiconductor layer; and
the ions of at least one electrically inactive dopant species are implanted through the second doped compound semiconductor layer into portions of the active layer prior to attaching the array of light emitting diodes to the backplane.

19. The method of claim 16, wherein:
the patterned ion implantation mask layer is formed over the first doped compound semiconductor layer; and
the ions of at least one electrically inactive dopant species are implanted through the first doped compound semiconductor layer into portions of the active layer and into portions of the second doped compound semiconductor layer after attaching the array of light emitting diodes to the backplane, after detaching the substrate, and prior to forming the common transparent conductive n-side electrode.

20. The method of claim 13, wherein the at least one electrically inactive dopant species comprises oxygen or nitrogen.
